(19) United States
(12) Patent Application Publication
(10) Pub. No.: US 2026/0074706 A1
(43) Pub. Date: Mar. 12, 2026

(54) CYCLIC ANALOG-TO-DIGITAL CONVERTER AND INTEGRATED CIRCUIT INCLUDING THE SAME

(71) Applicant: Samsung Electronics Co., Ltd., Suwon-si (KR)

(72) Inventors: Wonseon LEE, Suwon-si (KR); Youngcheol CHAE, Seoul (KR)

(73) Assignees: Samsung Electronics Co., Ltd., Suwon-si (KR); UIF (University Industry Foundation), Yonsei University, Seoul (KR)

(21) Appl. No.: 19/220,947

(22) Filed: May 28, 2025

(30) Foreign Application Priority Data
Sep. 6, 2024 (KR) 10-2024-0121241
Nov. 28, 2024 (KR) 10-2024-0173335

(51) Int. Cl. H03M 1/06

(52) U.S. Cl. CPC H03M 1/0604

(57) ABSTRACT

Acyclic analog-to-digital converter includes an input network configured to receive a first analog signal and a first compensation signal, and to output a second analog signal based on the first analog signal and the first compensation signal, the input network including at least one resistor in a path for transmitting the first analog signal, the first and second analog signals being continuous signals, a quantizer configured to output a digital signal based on the second analog signal and a second compensation signal, a first compensation circuit configured to output the first compensation signal based on the digital signal, and a second compensation circuit configured to output the second compensation signal based on the digital signal.

### CROSS-REFERENCE TO RELATED APPLICATION

This application claims priority under 35 USC § 119 to Korean Patent Application No. 10-2024-0121241 filed on Sep. 6, 2024 and to Korean Patent Application No. 10-2024-0173335 filed on Nov. 28, 2024 in the Korean Intellectual Property Office (KIPO), the contents of which are herein incorporated by reference in their entirety.

### BACKGROUND

Analog-to-digital converters are apparatuses configured to convert analog signals into digital signals, and are used in many electronic device applications. For example, an analog-digital-converter may receive an input signal having an analog form that represents a continuous value, and convert the input signal into an output signal having a digital form (n-bits) that represents a discrete value.

A major reason for converting analog signals into digital signals is to effectively store, process, and reproduce signals. Recently, with the development of digital technology, almost all information are converted from analog signals into digital signals and are processed accordingly.

To operate the analog-to-digital converter with low power, not only the power used in the analog-to-digital converter should be reduced, but the power used in an input driver in front of the analog-to-digital converter also should be reduced. Various technologies are being studied in this regard.

### SUMMARY

At least one example embodiment of the inventive concepts provides a cyclic analog-to-digital converter capable of operating without a sample-and-hold circuit.

At least one example embodiment of the inventive concepts provides an integrated circuit including the cyclic analog-to-digital converter.

According to some example embodiments, a cyclic analog-to-digital converter includes an input network configured to receive a first analog signal and a first compensation signal, and to output a second analog signal based on the first analog signal and the first compensation signal, the input network including at least one resistor in a path for transmitting the first analog signal, the first and second analog signals being continuous signals, a quantizer configured to output a digital signal based on the second analog signal and a second compensation signal, a first compensation circuit configured to output the first compensation signal based on the digital signal, and a second compensation circuit configured to output the second compensation signal based on the digital signal.

According to some example embodiments, an integrated circuit includes a cyclic analog-to-digital converter configured to perform an analog-to-digital conversion, and an internal circuit configured to transmit a first analog signal to the cyclic analog-to-digital converter, or to operate based on a digital signal output from the cyclic analog-to-digital converter, the first analog signal being a continuous signal, and the cyclic analog-to-digital converter including an input network configured to output a second analog signal based on the first analog signal and a first compensation signal, the input network including at least one resistor in a path for transmitting the first analog signal, the second analog signal being a continuous signal, a quantizer configured to output the digital signal based on the second analog signal and a second compensation signal, a first compensation circuit configured to output the first compensation signal based on the digital signal, and a second compensation circuit configured to output the second compensation signal based on the digital signal.

According to some example embodiments, a cyclic analog-to-digital converter includes an operational amplifier including a first input terminal configured to receive a first analog signal and a first compensation signal, a second input terminal connected to a ground voltage, and an output terminal configured to output a second analog signal, the operational amplifier configured to output the second analog signal based on the first analog signal and the first compensation signal, the first and second analog signals being continuous signals, a first resistor connected to the first input terminal of the operational amplifier, a first capacitor connected between the first input terminal and the output terminal of the operational amplifier, a first switch is connected between the first input terminal and the output terminal of the operational amplifier, the first switch configured to initialize the second analog signal, a second capacitor and a second switch connected in series between the first input terminal and the output terminal of the operational amplifier, a feedback resistor connected between the first input terminal and the output terminal of the operational amplifier, the feedback resistor configured to output a feedback signal based on the second analog signal, a quantizer configured to output a digital signal based on the second analog signal, a second compensation signal, and a first clock signal, a first digital-to-analog converter configured to output the first compensation signal based on the digital signal and a second clock signal, the second clock signal being delayed from the first clock signal, and a second digital-to-analog converter configured to output the second compensation signal based on the digital signal and the second clock signal.

According to some example embodiments, a method for generating a digital signal based on a first analog signal includes, receiving, by an input network including at least one resistor arranged in a path for transmitting a first analog signal, the first analog signal and a first compensation signal, the first analog signal being a continuous signal, outputting, by the input network, a second analog signal based on the first analog signal and the first compensation signal, the second analog signal being a continuous signal, outputting, by a quantizer, a digital signal based on the second analog signal and a second compensation signal, and outputting, by a first compensation circuit, the first compensation signal based on the digital signal, and outputting, by a second compensation circuit, the second compensation signal based on the digital signal.

According to some example embodiments, the method may further include outputting, by a feedback circuit, a feedback signal based on the second analog signal, and outputting, by an integrator, the second analog signal based on the first analog signal, the feedback signal, and the first compensation signal.

According to some example embodiments, integrator may include an operational amplifier including a first input terminal configured to receive the first analog signal and the first compensation signal, a second input terminal connected to a ground voltage, and an output terminal configured to output the second analog signal, a first resistor connected to the first input terminal of the operational amplifier, and a first capacitor connected between the first input terminal and the output terminal of the operational amplifier.

According to some example embodiments, the feedback circuit may include a feedback resistor connected between the first input terminal and the output terminal of the operational amplifier, and the method may further include determining a voltage level of the feedback signal based on a feedback gain of the feedback circuit, the feedback gain being based on a resistance of the feedback resistor and a capacitance of the first capacitor.

According to some example embodiments, the method may further include determining a voltage level of a difference signal based on a first gain of the integrator, the first gain based on a resistance of the first resistor and a capacitance of the first capacitor, and the difference signal corresponds to a difference between the first analog signal and the first compensation signal.

According to some example embodiments, the method may further include converting, by a first digital-to-analog converter, the digital signal into the first compensation signal.

According to some example embodiments, the method may further include determining a voltage level of the first compensation signal based on a second gain of the first compensation circuit, the second gain being based on a resistance of an internal resistor of the first digital-to-analog converter and a capacitance of the first capacitor.

According to some example embodiments, the method may further include operating the quantizer based on a first clock signal, and operating the first digital-to-analog converter based on a second clock signal which is delayed from the first clock signal.

According to some example embodiments, the method may further include converting, by a second digital-to-analog converter, the digital signal into the second compensation signal.

According to some example embodiments, a resistor may be connected between the input network and the quantizer.

According to some example embodiments, the method may further include determining a voltage level of the second analog signal based on a third gain, and determining a voltage level of the second compensation signal based on a fourth gain, wherein a ratio of the third gain and the fourth gain is based on a ratio of a resistance of an internal resistor of the second digital-to-analog converter and a resistance of the second resistor.

According to some example embodiments, the method may further include operating the quantizer based on a first clock signal, and operating the second digital-to-analog converter based on a third clock signal which is delayed from the first clock signal.

According to some example embodiments, the method may further include initializing, by a reset circuit connected between the first input terminal and the output terminal of the operational of the integrator, the second analog signal.

According to some example embodiments, the reset circuit may include a first switch connected between the first input terminal and the output terminal of the operational amplifier.

According to some example embodiments, the integrator may further include a second capacitor and a second switch connected in series between the first input terminal and the output terminal of the operational amplifier.

According to some example embodiments, the integrator may further include a negative impedance converter connected between the first input terminal and the second input terminal of the operational amplifier.

In the cyclic analog-to-digital converter and the integrated circuit according to example embodiments, the input network including resistors and RC integrators may be designed without the sample-and-hold circuit, and the cyclic analog-to-digital converter including the input network may operate in continuous time. Therefore, not only the power used in the analog-to-digital converter may be reduced, but the power used in the input driver in front of the analog-to-digital converter also may be reduced, such that a power efficiency of the entire system may be increased. A hardware area also may be reduced by omitting the sample-and-hold circuit.

In addition, when the cyclic analog-to-digital converter operates in continuous time, a loop delay may occur, and the loop delay may be compensated for by using two compensation circuits.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a cyclic analog-to-digital converter according to some example embodiments.

FIG. 2 is a circuit diagram illustrating an example of an input network included in a cyclic analog-to-digital converter according to some example embodiments.

FIG. 3 is a circuit diagram for describing an operation of an input network of FIG. 2.

FIG. 4 is a diagram illustrating a cyclic analog-to-digital converter according to some example embodiments.

FIG. 5 is a diagram for describing an operation of a cyclic analog-to-digital converter of FIG. 4.

FIG. 6 is a diagram illustrating a cyclic analog-to-digital converter according to some example embodiments.

FIG. 7 is a circuit diagram illustrating an example of an input network included in a cyclic analog-to-digital converter according to some example embodiments.

FIG. 8 is a circuit diagram illustrating an example of an input network included in a cyclic analog-to-digital converter according to some example embodiments.

FIG. 9 is a circuit diagram illustrating an example of an input network included in a cyclic analog-to-digital converter according to some example embodiments.

FIG. 10 is a circuit diagram illustrating an example of a negative impedance converter included in an integrator in FIG. 9.

FIG. 11 is a block diagram illustrating an integrated circuit according to some example embodiments.

FIG. 12 is a block diagram illustrating an electronic system according to some example embodiments.

### DETAILED DESCRIPTION OF THE EMBODIMENTS

Various example embodiments will be described more fully with reference to the accompanying drawings, in which some example embodiments are shown. The inventive concepts may, however, be embodied in many different forms and should not be construed as limited to the example embodiments set forth herein. Like reference numerals refer to like elements throughout this application.

When the words “about” and “substantially” are used in this application in connection with a numerical value, it is intended that the associated numerical value include a tolerance of ±10% around the stated numerical value, unless otherwise explicitly defined. Further, regardless of whether numerical values are modified as “about” or “substantially,” it will be understood that these values should be construed as including a of ±10% around the stated numerical value.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

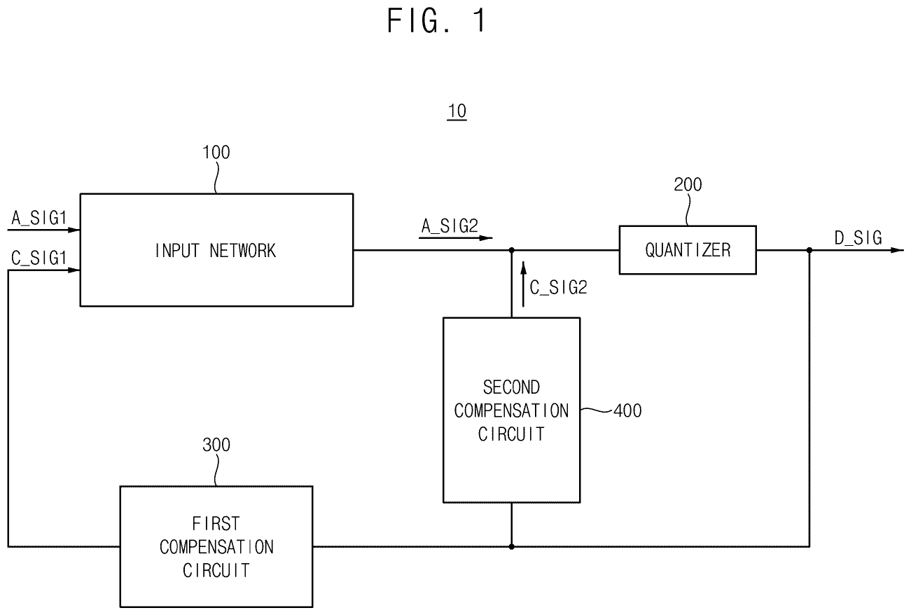

FIG. 1 is a block diagram illustrating a cyclic analog-to-digital converter according to some example embodiments.

Referring to FIG. 1, a cyclic analog-to-digital converter 10 includes an input network 100, a quantizer 200, a first compensation circuit 300, and/or a second compensation circuit 400.

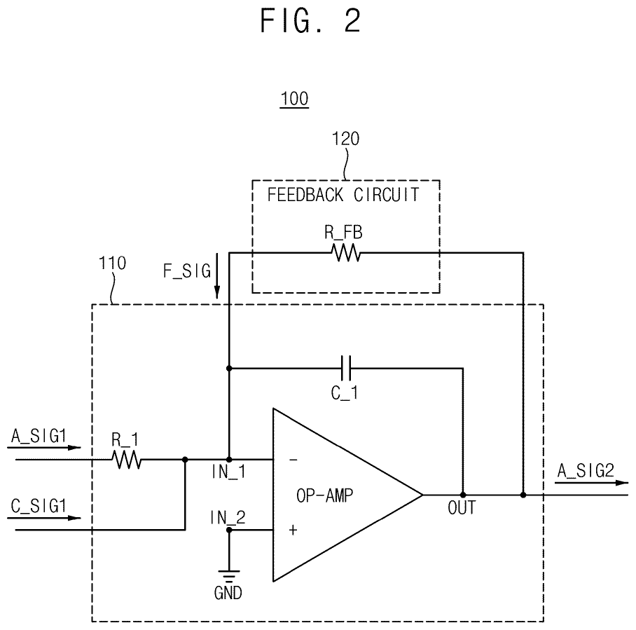

The input network 100 receives a first analog signal A_SIG1 and/or a first compensation signal C_SIG1, and outputs a second analog signal A_SIG2 based on the first analog signal A_SIG1 and/or the first compensation signal C_SIG1. The first analog signal A_SIG1 and the second analog signal A_SIG2 are continuous signals. The input network 100 includes at least one resistor arranged in a path for transmitting the first analog signal A_SIG1. An example configuration of the input network 100 will be described with reference to FIG. 2, etc.

The first analog signal A_SIG1 may be an input signal of the input network 100, and the second analog signal A_SIG2 may be an output signal of the input network 100. Thus, when both the first analog signal A_SIG1 and the second analog signal A_SIG2 are continuous signals, the input network 100 may operate in continuous time (or continuous time domain).

The quantizer 200 outputs a digital signal D_SIG based on the second analog signal A_SIG2 and/or a second compensation signal C_SIG2. The quantizer 200 performs an operation of converting an analog signal, which is a continuous signal, into a digital signal.

For example, if a quantization bit is two bits, the quantizer 200 may extract an analog value from an analog signal at regular time intervals, map the extracted analog value into one of digital values of zero, one, two, and three, and output a digital signal having the mapped digital value. For example, if a quantization bit is four bits, the quantizer 200 may extract an analog value from an analog signal at regular time intervals, map the extracted analog value into one of digital values of zero, one, two, three, four, five, six, seven, eight, nine, ten, eleven, twelve, thirteen, fourteen, and fifteen, and output a digital signal having the mapped digital value.

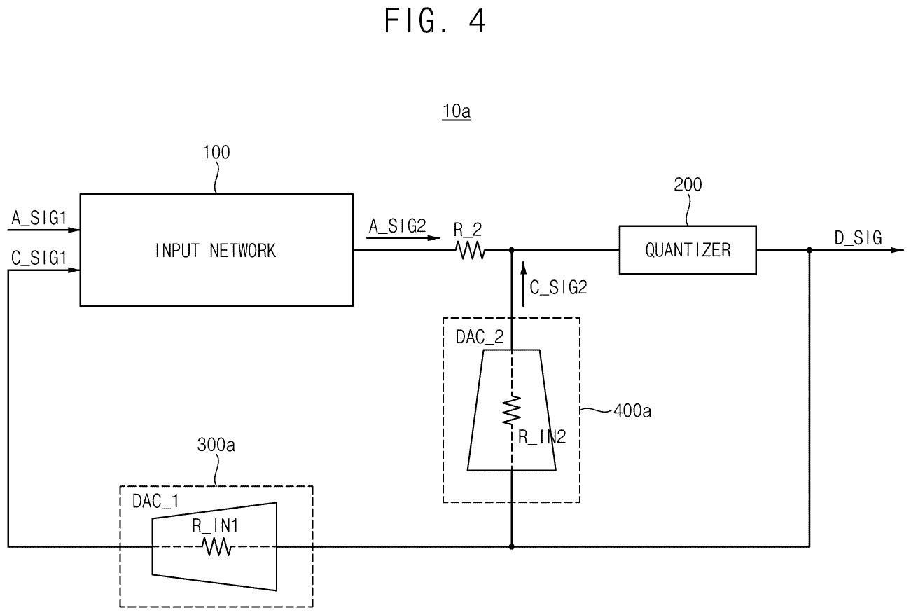

The first compensation circuit 300 outputs the first compensation signal C_SIG1 based on the digital signal D_SIG. The first compensation circuit 300 may perform an operation of compensating for a loop delay which may occur when the input network 100 and the cyclic analog-to-digital converter 10 including the input network 100 operate in continuous time. For example, the first compensation circuit 300 may perform an operation of compensating for an output signal in which the loop delay occurs by multiplying the output signal by a specific value. Example configuration and operation of the first compensation circuit 300 will be described with reference to FIGS. 4, 5, and 6.

The second compensation circuit 400 outputs the second compensation signal C_SIG2 based on the digital signal D_SIG. Similarly to the first compensation circuit 300, the second compensation circuit 400 may perform an operation of compensating for the loop delay which may occur when the cyclic analog-to-digital converter 10 operates in continuous time. For example, the second compensation circuit 400 may perform an operation of compensating for the output signal in which the loop delay occurs by adding a specific value to an initial value of the output signal. Example configuration and operation of the second compensation circuit 400 will be described with reference to FIGS. 4, 5, and 6.

A conventional cyclic analog-to-digital converter includes a sample-and-hold circuit which receives an analog signal, which is a continuous signal, and performs an operation of sampling the analog signal. Since the sample-and-hold circuit has high linearity, a relatively large hardware area and a relatively large amount of power may be required. The sample-and-hold circuit may include a plurality of switches and/or a plurality of capacitors. Due to a dynamic current and/or peak current generated from the switching operation of the switches and the charging/discharging operation of the capacitors, the sample-and-hold circuit and/or the input driver in front of the sample-and-hold circuit require large amount of power.

In the cyclic analog-to-digital converter 10 according to some example embodiments, the input network 100 including resistors and/or RC integrators may be designed without the sample-and-hold circuit, and the cyclic analog-to-digital converter 10 including the input network 100 may operate in continuous time. Therefore, not only the power used in the cyclic analog-to-digital converter 10 may be reduced, but the power used in the input network 100 in front of the cyclic analog-to-digital converter 10 also may be reduced, such that a power efficiency of the entire system may be increased. A hardware area also may be reduced by omitting the sample-and-hold circuit.

For example, when the cyclic analog-to-digital converter 10 operates in continuous time, the loop delay may occur, and the loop delay may be compensated for by using the first compensation circuit 300 and/or the second compensation circuit 400.

FIG. 2 is a circuit diagram illustrating an example of an input network included in a cyclic analog-to-digital converter according to some example embodiments.

Referring to FIG. 2, the input network 100 may include an integrator 110 and/or a feedback circuit 120.

The integrator 110 may include an operational amplifier OP-AMP, a first resistor R_1, and/or a first capacitor C_1. The operational amplifier OP-AMP may include a first input terminal IN_1 receiving the first analog signal A_SIG1 and/or the first compensation signal C_SIG1, a second input terminal IN_2 connected to a ground voltage GND, and/or an output terminal OUT outputting the second analog signal A_SIG2.

Although FIG. 2 illustrates an example where the first analog signal A_SIG1 and the first compensation signal C_SIG1 are single ended signals, example embodiments are not limited thereto, and the first analog signal A_SIG1 and the first compensation signal C_SIG1 may be differential signals. For example, if the first analog signal A_SIG1 is first differential signals and the first compensation signal C_SIG1 is second differential signals, a wire transmitting one of the first differential signals corresponding to a first phase and a wire transmitting one of the second differential signals corresponding to a second phase may be connected to each other. For example, a wire transmitting the other one of the first differential signals corresponding to a second phase and a wire transmitting the other one of the second differential signals corresponding to a first phase may be connected to each other.

For example, the integrator 110 may perform an integration operation on a difference between the first analog signal A_SIG1 and the first compensation signal C_SIG1, and output a result of the integration operation as the second analog signal A_SIG2. In other words, the first compensation circuit (e.g., 300 in FIG. 1) may perform a negative feedback operation.

For example, as illustrated in FIG. 2, the first input terminal IN_1 may represent an inverting input terminal of the operational amplifier OP-AMP, and the second input terminal IN_2 may represent a non-inverting input terminal of the operational amplifier OP-AMP. However, example embodiments are not limited thereto, and the first input terminal IN_1 may represent the non-inverting input terminal of the operational amplifier OP-AMP, and the second input terminal IN_2 may represent the inverting input terminal of the operational amplifier OP-AMP.

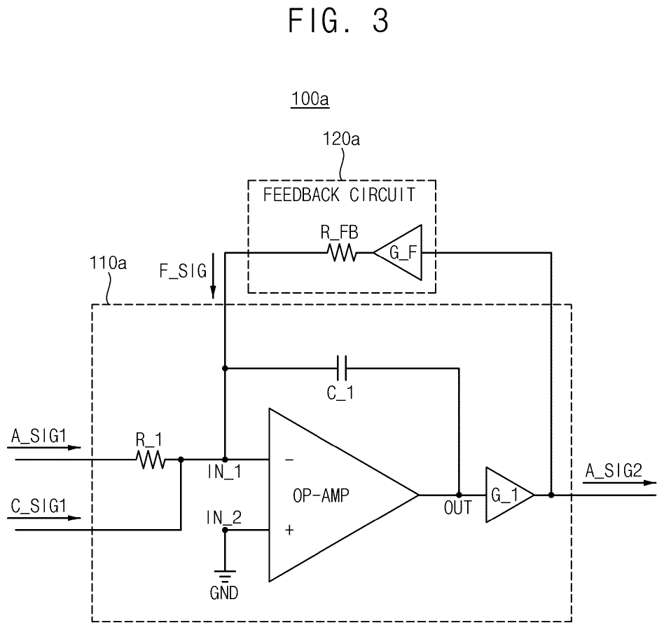

The first resistor R_1 may be connected to the first input terminal IN_1. For example, the first resistor R_1 may be included in the at least one resistor arranged in the path for transmitting the first analog signal A_SIG1, which is described with reference to FIG. 1. For example, the first resistor R_1 may perform an operation of controlling charging/discharging speed of the first capacitor C_1. The first resistor R_1 may be a factor for determining a time constant. For example, a first gain for determining a voltage level of a difference signal may be set based on a resistance of the first resistor R_1 and a capacitance of the first capacitor C_1, and the difference signal may correspond to a difference between the first analog signal A_SIG1 and the first compensation signal C_SIG1. The first gain and the operation of setting the first gain will be described with reference to FIG. 3.

The first capacitor C_1 may be connected between the first input terminal IN_1 and the output terminal OUT of the operational amplifier OP-AMP. The first capacitor C_1 may perform an operation of storing and/or releasing charges whenever the input signal changes in the operation of the integrator 110. Although FIG. 2 illustrates only one capacitor, example embodiments are not limited thereto, and a plurality of capacitors may be connected in parallel between the first input terminal IN_1 and the output terminal OUT of the operational amplifier OP-AMP.

The feedback circuit 120 may include a feedback resistor R_FB connected between the first input terminal IN_1 and the output terminal OUT of the operational amplifier OP-AMP. The feedback circuit 120 may output a feedback signal F_SIG based on the second analog signal A_SIG2.

For example, the feedback circuit 120 may perform an operation of amplifying and/or attenuating the second analog signal A_SIG2 by a feedback gain and transmitting the amplified and/or attenuated signal to the first input terminal IN_1 of the operational amplifier OP-AMP. For example, the feedback gain for determining a voltage level of the feedback signal F_SIG may be set based on a resistance of the feedback resistor R_FB and/or the capacitance of the first capacitor C_1. The feedback gain and the operation of setting the feedback gain will be described with reference to FIG. 3.

For example, the feedback circuit 120 may perform a positive feedback operation. For example, if the difference signal between the first analog signal A_SIG1 and the first compensation signal C_SIG1 is third differential signal, and the feedback signal F_SIG is fourth differential signal, a wire transmitting one of the third differential signals corresponding to a third phase and a wire transmitting one of the fourth differential signals corresponding to a third phase among the differential signals of the feedback signal F_SIG may be connected to each other.

FIG. 3 is a circuit diagram for describing an operation of an input network of FIG. 2.

Referring to FIG. 3, an input network 100a may include an integrator 110a and/or a feedback circuit 120a. The integrator 110a may further include a component having a first gain G_1 compared to the integrator 110 in FIG. 2. The feedback circuit 120a may further include a component having a feedback gain G_F compared to the feedback circuit 120 in FIG. 2. Hereinafter, the descriptions repeated with or overlapping with descriptions of FIG. 2 will be omitted in the interest of brevity.

The component having the first gain G_1 may not be a component that physically exists in the integrator 110a, and may be a component conceptually added to describe the first gain G_1. For example, the first gain G_1 may be a gain of the integrator 110a.

Likewise, the component having the feedback gain G_F may not be component that physically exists in the feedback circuit 120a, and may be a component and/or conceptually added to describe the feedback gain G_F. The feedback gain G_F may be a gain of the feedback circuit 120a.

For example, a gain of the input network 100a for determining a voltage level of the second analog signal A_SIG2 may be set based on the first gain G_1 and the feedback gain G_F.

For example, the voltage level of the difference between the voltage level of the first analog signal A_SIG1 and the first compensation signal C_SIG1 may be amplified or attenuated by the first gain G_1. The first gain G_1 may be set based on the resistance of the first resistor R_1 and the capacitance of the first capacitor C_1.

For example, the first gain G_1 may be a reciprocal of a product of the resistance of the first resistor R_1, the capacitance of the first capacitor C_1, and a sampling frequency. For example, if the resistance of the first resistor R_1 is about 2KΩ, the capacitance of the first capacitor C_1 is about 10 pF, and the sampling frequency is about 100 MHz, the first gain G_1 may be about 0.5. In this case, the voltage level of the difference between the voltage level of the first analog signal A_SIG1 and the first compensation signal C_SIG1 may be attenuated by 0.5 times.

For example, a voltage level of the feedback signal F_SIG may be amplified and/or attenuated by the feedback gain G_F. The feedback gain G_F may be set based on the resistance of the feedback resistor R_FB and the capacitance of the first capacitor C_1. For example, the feedback gain G_F may be a reciprocal of a product of the resistance of the feedback resistor R_FB, the capacitance of the first capacitor C_1, and the sampling frequency. For example, if the resistance of the feedback resistor R_FB is about 4KΩ, the capacitance of the first capacitor C_1 is about 10 pF, and the sampling frequency is about 100 MHz, the feedback gain G_F may be 0.25. In this case, the voltage level of the second analog signal A_SIG2 may be attenuated by 0.25 times and transmitted back to the first input terminal IN_1 of the operational amplifier OP-AMP.

FIG. 4 is a diagram illustrating a cyclic analog-to-digital converter according to example embodiments.

Referring to FIG. 4, a cyclic analog-to-digital converter 10a includes the input network 100, the quantizer 200, a first compensation circuit 300a, and/or a second compensation circuit 400a, and may further include a second resistor R_2. The first compensation circuit 300a may include a first digital-to-analog converter DAC_1. The second compensation circuit 400a may include a second digital-to-analog converter DAC_2. Hereinafter, the descriptions repeated with or overlapping with descriptions of FIG. 1 will be omitted in the interest of brevity.

The second resistor R_2 may be connected between the input network 100 and the quantizer 200. For example, a third gain for determining an amplified and/or attenuated voltage level of the second analog signal A_SIG2 may be inversely proportional to a resistance of the second resistor R_2.

The first digital-to-analog converter DAC_1 may convert the digital signal D_SIG into the first compensation signal C_SIG1. Although there are a plurality of resistances of components inside the first digital-to-analog converter DAC_1, a resistor having a resistance equivalent to the plurality of resistances of the components may be defined as a first internal resistor R_IN1 of the first digital-to-analog converter DAC_1, for convenience.

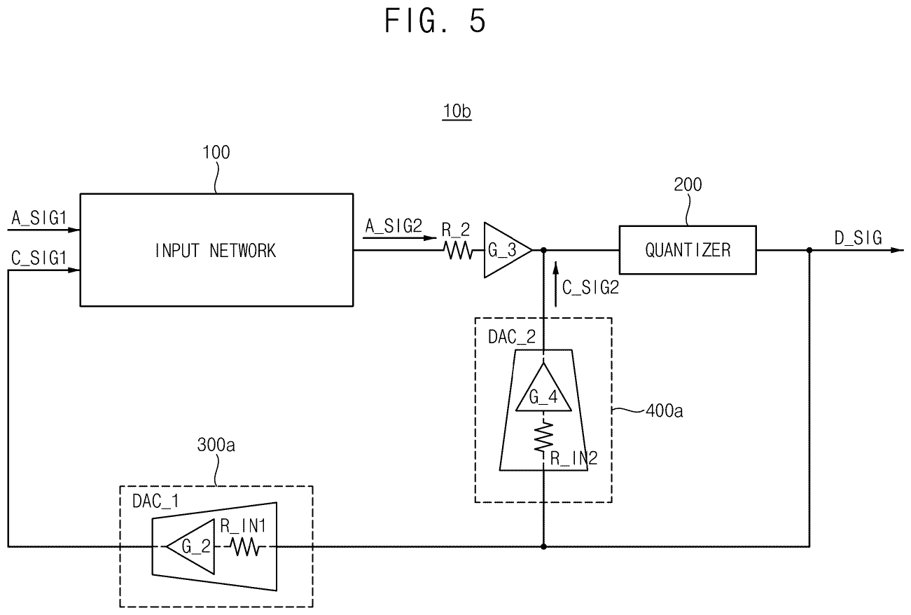

For example, the digital signal D_SIG may be amplified and/or attenuated by a second gain for determining the voltage level of the first compensation signal C_SIG1 through the first digital-to-analog converter DAC_1 and output as the first compensation signal C_SIG1, which is an analog signal. For example, the second gain for determining the level of the first compensation signal C_SIG1 may be set based on a resistance of the first internal resistor R_IN1 of the first digital-to-analog converter DAC_1 and/or the capacitance of the first capacitor (e.g., C_1 in FIG. 2) of the integrator. The second gain and the operation of setting the second gain will be described with reference to FIG. 5.

The second digital-to-analog converter DAC_2 may convert the digital signal D_SIG into the second compensation signal C_SIG2. Although there are a plurality of resistances of components inside the second digital-to-analog converter DAC_2, a resistor having a resistance equivalent to the plurality of resistances of the components may be defined as a second internal resistor R_IN2 of the second digital-to-analog converter DAC_2, for convenience.

For example, the digital signal D_SIG may be amplified and/or attenuated by a fourth gain for determining a voltage level of the second compensation signal C_SIG2 through the second digital-to-analog converter DAC_2 and output as the second compensation signal C_SIG2, which is an analog signal. For example, the fourth gain for determining the voltage level of the second compensation signal C_SIG2 may be inversely proportional to a resistance of the second internal resistor R_IN2 of the second digital-to-analog converter DAC_2. The fourth gain and the operation of setting the fourth gain will be described with reference to FIG. 5.

Although FIG. 4 illustrates an example where the second analog signal A_SIG2 and the second compensation signal C_SIG2 are single ended signals, example embodiments are not limited thereto, and the second analog signal A_SIG2 and/or the second compensation signal C_SIG2 may be differential signals. For example, if the second analog signal A_SIG2 is fifth differential signals and the second compensation signal C_SIG2 is sixth differential signals, a wire transmitting one of the fifth differential signals corresponding to a fifth phase and a wire transmitting one of the sixth differential signals corresponding to a sixth phase may be connected to each other. For example, a wire transmitting the other one of the fifth differential signals corresponding to a sixth phase and a wire transmitting the other one of the sixth differential signals corresponding to a fifth phase may be connected to each other.

For example, the quantizer 200 may perform a quantization operation on a difference between the second analog signal A_SIG2 and the second compensation signal C_SIG2 and output a result of the operation of quantization as the digital signal D_SIG. In other words, the second compensation circuit 400a may perform the negative feedback operation.

FIG. 5 is a diagram for describing an operation of a cyclic analog-to-digital converter of FIG. 4.

Referring to FIG. 5, a cyclic analog-to-digital converter 10b may further include a component having a second gain G_2, a component having a third gain G_3, and/or a component having a fourth gain G_4 compared to the cyclic analog-to-digital converter 10a of FIG. 4. Hereinafter, the descriptions repeated with or overlapping with descriptions of FIG. 4 will be omitted in the interest of brevity.

The component having the second gain G_2, the component having the third gain G_3, and/or the component having the fourth gain G_4 may not be components that physically exist in the cyclic analog-to-digital converter 10b, and may be components conceptually added to describe the second gain G_2, the third gain G_3, and/or the fourth gain G_4. The second gain G_2 may be a gain of the first digital-to-analog converter DAC_1, and the fourth gain G_4 may be a gain of the second digital-to-analog converter DAC_2. The third gain G_3 may be a gain for determining the amplified or attenuated voltage level of the second analog signal A_SIG2.

For example, the digital signal D_SIG may be amplified and/or attenuated by the second gain G_2 and output as the first compensation signal C_SIG1. For example, the second gain G_2 may be set based on the resistance of the first internal resistor R_IN1 of the first digital-to-analog converter DAC_1 and the capacitance of the first capacitor (e.g., C_1 in FIG. 2) of the integrator.

For example, the second gain G_2 may be a reciprocal of a product of the resistance of the first internal resistor R_IN1, the capacitance of the first capacitor C_1, and the sampling frequency. For example, if the resistance of the first internal resistor R_IN1 is about 2KΩ, the capacitance of the first capacitor C_1 is about 10 pF, and the sampling frequency is 100 MHz, the second gain G_2 may be 0.5. In this case, the digital signal D_SIG may be attenuated by 0.5 times and output as the first compensation signal C_SIG1.

For example, the voltage level of the second analog signal A_SIG2 may be amplified and/or attenuated by the third gain G_3, and the digital signal D_SIG may be amplified and/or attenuated by the fourth gain G_4 and output as the second compensation signal C_SIG2. The ratio of the third gain G_3 for determining the amplified and/or attenuated voltage level of the second analog signal A_SIG2 and the fourth gain G_4 for determining the voltage level of the second compensation signal C_SIG2 may be set based on the ratio of the resistance of the second internal resistor R_IN2 of the second digital-to-analog converter DAC_2 and the resistance of the second resistor R_2.

For example, a value obtained by dividing the third gain G_3 by the fourth gain G_4 may be a value obtained by dividing the resistance of the second internal resistor R_IN2 by the resistance of the second resistor R_2. For example, if the resistance of the second resistor R_2 is about 1KΩ and the resistance of the second internal resistor R_IN2 is about 2KΩ, the value of the third gain G_3 divided by the fourth gain G_4 may be 2. For example, if the resistance of the second resistor R_2 is about 2KΩ and the resistance of the second internal resistor R_IN2 is about 1KΩ, the value of the third gain G_3 divided by the fourth gain G_4 may be ½.

For example, in the conventional cyclic analog-to-digital converter including the sample-and-hold circuit, assuming an open-loop circuit without a main feedback circuit corresponding to the first compensation circuit 300a, a transfer function H1 may be defined as [Equation 1].

$$H 1 = \frac{1}{z - a} \qquad [ Equation 1 ]$$

In the [Equation 1], ‘z’ represents a variable in Z domain, and ‘a’ represents the feedback gain of the feedback circuit connected to the integrator.

If Z inverse transform is performed on the transfer function H1, an output signal D1[n] when a sampling period has passed n times may be defined as [Equation 2].

$$D 1 [ n ] = {a}^{n} \qquad [ Equation 2 ]$$

For example, assuming that the cyclic analog-to-digital converter 10b according to some example embodiments does not include the first compensation circuit 300a and/or the second compensation circuit 400a, the transfer function H2 may be defined as [Equation 3].

$$H 2 = \frac{1}{s - b} \qquad [ Equation 3 ]$$

In the [Equation 3], ‘s’ represents a variable in S domain, and ‘b’ represents the feedback gain of the feedback circuit connected to the integrator.

If Laplace inverse transform is performed on the transfer function H2, an output signal D2(t) at time t may be equal to [Equation 4].

$$D 2 ( t ) = {e}^{bt} \qquad [ Equation 4 ]$$

The transfer function H2 of the cyclic analog-to-digital converter 10b according to some example embodiments and the transfer function H1 of the conventional cyclic analog-to-digital converter should perform the same function with only the difference in the S domain and the Z domain, so the ratio of the output signal D2[n] and D2[n+1] when the sampling period of the cyclic analog-to-digital converter 10b according to some example embodiments has passed n times may be equal to the feedback gain ‘a’ in the conventional cyclic analog-to-digital converter.

For example, in the cyclic analog-to-digital converter 10b according to some example embodiments, if the loop delay does not occur, the output signal D2[1] when the sampling period has passed once may be one, the output signal D2[2] when the sampling period has passed twice may be ‘a’, the output signal D2[3] when the sampling period has passed three times may be ‘a²’, and the output signal D2[4] when the sampling period has passed four times may be ‘a³’.

For example, assuming that the cyclic analog-to-digital converter 10b according to some example embodiments does not include the first compensation circuit 300a and the second compensation circuit 400a, if the loop delay occurs as much as the sampling period, the output signal D2[1] when the sampling period has passed once may be zero, the output signal D2[2] when the sampling period has passed twice may be one, the output signal D2[3] when the sampling period has passed three times may be ‘a’, and the output signal D2[4] when the sampling period has passed four times may be ‘a²’.

In the cyclic analog-to-digital converter 10b according to example embodiments, the first compensation circuit 300a may perform the operation of compensating for the output signal in which the loop delay occurs by multiplying the output signal by ‘a’. For example, the second gain G_2 of the first compensation circuit 300a may be ‘a’.

However, even after performing the operation of compensating by multiplying the output signal in which the loop delay occurs by ‘a’, since the output signal D2[1] when the sampling period has passed once may be zero, the loop delay may still exist.

Therefore, in the cyclic analog-to-digital converter 10b according to some example embodiments, the second compensation circuit 400a may perform the operation of compensating for the output signal in which the loop delay occurs by adding the specific value to the initial value of the output signal in which the loop delay occurs.

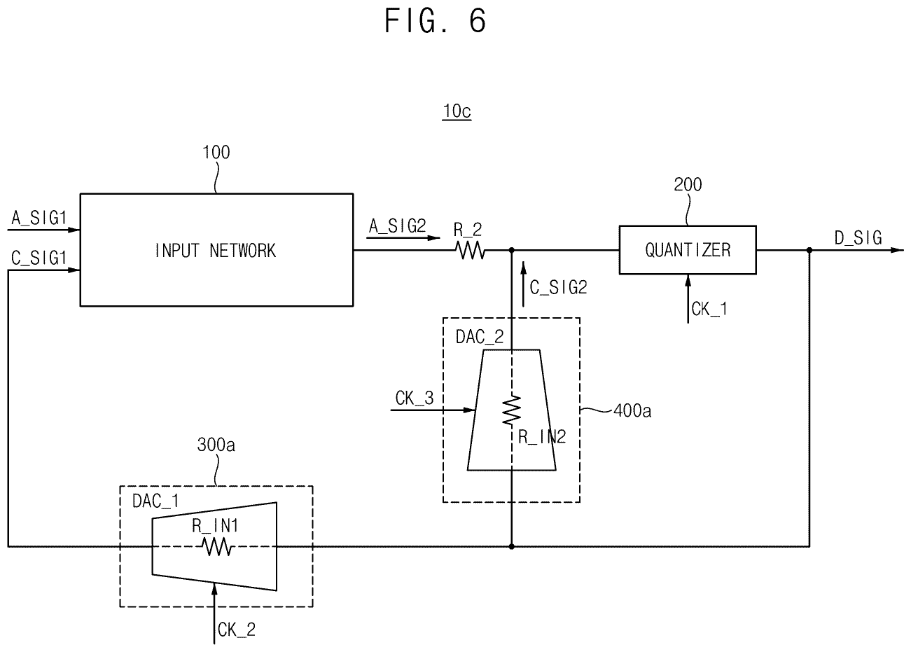

FIG. 6 is a diagram illustrating a cyclic analog-to-digital converter according to some example embodiments.

Referring to FIG. 6, a cyclic analog-to-digital converter 10c may receive a first clock signal CK_1 in the quantizer 200, a second clock signal CK_2 in the first digital-to-analog converter DAC_1, and/or a third clock signal CK_3 in the third digital-to-analog converter DAC_2, compared to the cyclic analog-to-digital converter 10 of FIG. 4. The remaining components may be substantially the same as in FIG. 4. Hereinafter, the descriptions repeated with or overlapping with descriptions of FIG. 4 will be omitted in the interest of brevity.

The first clock signal CK_1 is received in the quantizer 200, and the quantizer 200 may operate based on the first clock signal CK_1.

The first digital-to-analog converter DAC_1 may operate based on the second clock signal CK_2 which is delayed from the first clock signal CK_1.

For example, when the quantizer 200 performs the operation of quantization, the loop delay may occur. The conventional cyclic analog-to-digital converter includes the sample-and-hold circuit, and the sample-and-hold circuit may perform an operation of sampling for half a period within one period and an operation of holding for the remaining half period. Therefore, in the conventional cyclic analog-to-digital converter, the compensation signal or the feedback signal may be received during the half period in which the operation of holding is performed, such that the loop delay does not occur. Therefore, in the conventional cyclic analog-to-digital converter, there is no need to receive the second clock signal CK_2 which is delayed from the first clock signal CK_1.

However, since the cyclic analog-to-digital converter 10c according to some example embodiments does not include the sample-and-hold circuit, the loop delay may occur when the quantizer 200 performs the operation of quantization. Therefore, the first digital-to-analog converter DAC_1 may receive the second clock signal CK_2 which is delayed from the first clock signal CK_1.

The second digital-to-analog converter DAC_2 may operate based on the third clock signal CK_3 which is delayed from the first clock signal CK_1.

As described above, since the cyclic analog-to-digital converter 10c according to some example embodiments does not include the sample-and-hold circuit, the loop delay may occur when the quantizer 200 performs the operation of quantization. Therefore, the second digital-to-analog converter DAC_2 may receive the third clock signal CK_3 which is delayed from the first clock signal CK_1.

Although FIG. 6 illustrates a case where the second clock signal CK_2 and the third clock signal CK_3 are different signals, example embodiments are not limited thereto, and the second clock signal CK_2 and the third clock signal CK_3 may be the same signal.

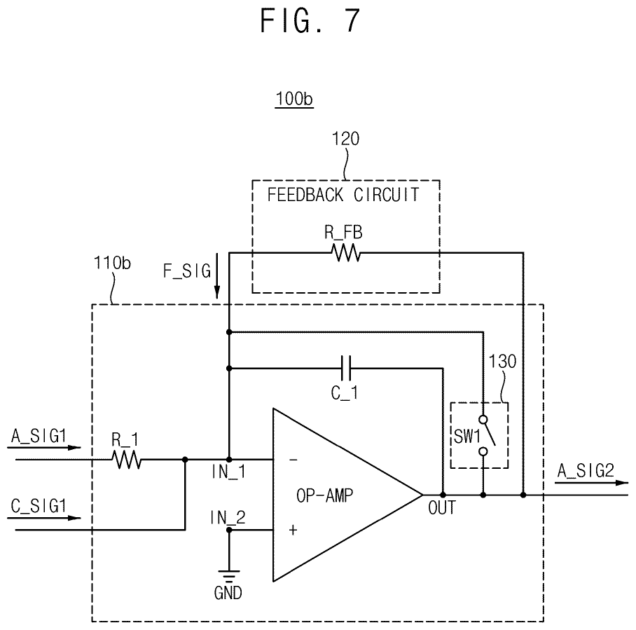

FIG. 7 is a circuit diagram illustrating an example of an input network included in a cyclic analog-to-digital converter according to example embodiments.

Referring to FIG. 7, an input network 100b may include an integrator 110b and/or the feedback circuit 120. The integrator 110b may further include a reset circuit 130 compared to the integrator 110 in FIG. 2. Hereinafter, the descriptions repeated with or overlapping with descriptions of FIG. 2 will be omitted in the interest of brevity.

The reset circuit 130 may be connected between the first input terminal IN_1 and the output terminal OUT of the operational amplifier OP-AMP, and may perform an operation of initializing the second analog signal A_SIG2. The reset circuit 130 may include a first switch SW1 connected between the first input terminal IN_1 and the output terminal OUT of the operational amplifier OP-AMP. For example, the first switch SW1 may receive a first switching signal (not illustrated) which is a digital signal and perform an operation of opening and closing based on the first switching signal.

For example, when the first switching signal has a logic high level, the first switch SW1 may be closed, and when the first switching signal has a logic low level, the first switch SW1 may be opened. However, example embodiments are not limited thereto, and when the first switching signal has a logic low level, the first switch SW1 may be opened, and when the first switching signal has a logic high level, the first switch SW1 may be closed.

For example, when the first switch SW1 is closed, the first input terminal IN_1 and the output terminal OUT of the operational amplifier OP-AMP may be short-circuited, and the second analog signal A_SIG2 may be initialized.

In other words, the reset circuit 130 may periodically initialize the input network 100b by the first switching signal. Since an analog-to-digital converter which periodically performs the operation of initializing is called an incremental analog-to-digital converter, a cyclic analog-to-digital converter including the input network 100b may be the incremental analog-to-digital converter. For example, in the incremental analog-to-digital converter which periodically performs the operation of initializing, components of a decimation filter, which is a filter performing an operation of lowering the sampling frequency, may be simplified.

For example, in the cyclic analog-to-digital converter according to some example embodiments, if the first analog input signal (e.g., A_SIG1 in FIG. 1) is ‘U’, the feedback gain (e.g., G_FB in FIG. 3) is ‘x’, the second gain (e.g., G_2 in FIG. 5) is ‘a_{fb}’, the second analog signal (e.g., A_SIG2 in FIG. 1) whose sampling period has passed M times is ‘V[M]’, and the digital signal (e.g., D_SIG in FIG. 1) whose sampling period has passed M times is ‘Y [M]’, then ‘U’ representing the first analog input signal A_SIG may be approximated by a recurrence relation as in [Equation 5].

$$\begin{matrix}V [ 1 ] = xV [ 0 ] + U - {a}_{fb} Y [ 1 ] \\ V [ 2 ] = xV [ 1 ] + U - {a}_{fb} Y [ 2 ] \\ V [ 2 ] = xU + UV [ 1 ] + U - {a}_{fb} Y [ 2 ] \\ V [ 3 ] = xV [ 2 ] + U - {a}_{fb} Y [ 3 ] \\ V [ 3 ] = {x}^{2} U + xU + U - {x}^{2} {a}_{fb} Y [ 1 ] - {xa}_{fb} Y [ 2 ] - {a}_{fb} Y [ 3 ] \\ ⋮ \\ V [ M ] = U [ 1 + x + {x}^{2} + ⋯ + {x}^{M - 1} ] - {a}_{fb} {{\sum }^{M}}_{i} Y [ i ] {x}^{M - 1} \\ U = \frac{{a}_{fb}}{G} {\sum }_{i = 1}^{M} Y [ i ] {x}^{M - 1} + \frac{V [ M ]}{G} , G = \frac{{x}^{M} - 1}{x - 1} , x = {e}^{{a}_{x}}\end{matrix} \qquad [ Equation 5 ]$$

In the [Equation 5], ‘G’ may mean a noise shaping factor.

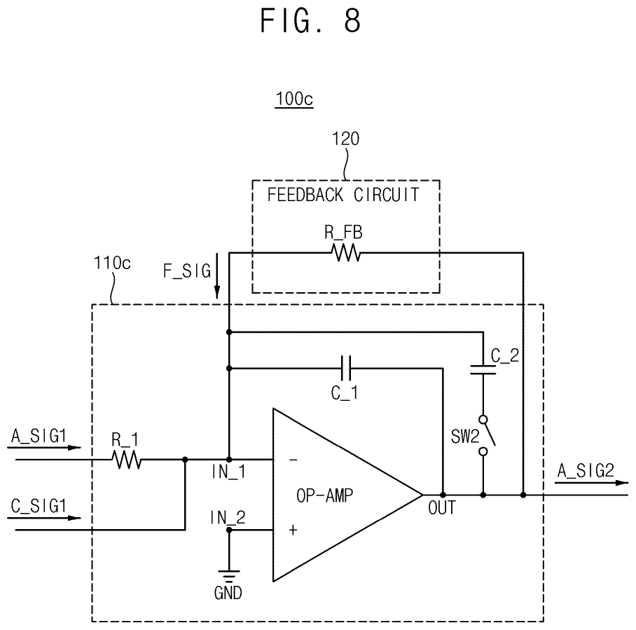

FIG. 8 is a circuit diagram illustrating an example of an input network included in a cyclic analog-to-digital converter according to example embodiments.

Referring to FIG. 8, an input network 100c may include an integrator 110c and/or the feedback circuit 120. The integrator 110c may further include a second capacitor C_2 and/or a second switch SW2 compared to the integrator 110 in FIG. 2. Hereinafter, the descriptions repeated with or overlapping with descriptions of FIG. 2 will be omitted in the interest of brevity.

The second capacitor C_2 and the second switch SW2 may be connected in series between the first input terminal IN_1 and the output terminal OUT of the operational amplifier OP-AMP. For example, the second switch SW2 may receive a second switching signal (not illustrated) which is a digital signal, and perform the operation of opening and/or closing operation based on the second switching signal.

For example, when the second switching signal has a logic high level, the second switch SW2 may be closed, and when the second switching signal has a logic low level, the second switch SW2 may be opened. However, example embodiments are not limited thereto, and when the second switching signal has a logic low level, the second switch SW2 may be opened, and when the second switching signal has a logic high level, the second switch SW2 may be closed.

For example, when the second switch SW2 is closed, the first capacitor C_1 and the second capacitor C_2 may be connected in parallel between the first input terminal IN_1 and the output terminal OUT of the operational amplifier OP-AMP. Therefore, a composite capacitance of the first capacitor C_1 and the second capacitor C_2 may be a sum of the capacitance of the first capacitor C_1 and the capacitance of the second capacitor C_2.

For example, if the capacitance of the first capacitor C_1 is 1 pF and the capacitance of the second capacitor C_2 is 1 pF, when the second switch SW2 is closed, the combined capacitance of the first capacitor C_1 and the second capacitor C_2 may be 2 pF.

Although FIG. 8 illustrates a case where one capacitor and one switch are connected between the first input terminal IN_1 and the output terminal OUT of the operational amplifier OP-AMP, example embodiments are not limited thereto, and two or more capacitors and two or more switches may be connected between the first input terminal IN_1 and the output terminal OUT of the operational amplifier OP-AMP. For example, a third capacitor (not illustrated) and a third switch (not illustrated) may be connected between the first input terminal IN_1 and the output terminal OUT of the operational amplifier OP-AMP, and a fourth capacitor (not illustrated) and a fourth switch (not illustrated) may be connected between the first input terminal IN_1 and the output terminal OUT of the operational amplifier OP-AMP.

As described above, when manufacturing the cyclic analog-to-digital converter according to some example embodiments, a plurality of capacitors and/or a plurality of switches may be connected between the first input terminal IN_1 and the output terminal OUT of the operational amplifier, or sufficient, OP-AMP, and the plurality of switches may be controlled to obtain a required composite capacitance of the capacitors.

For example, when the capacitance of the capacitor connected between the first input terminal IN_1 and the output terminal OUT of the operational amplifier OP-AMP changes, the first gain for voltage level of the difference signal, the feedback gain for determining the voltage level of the feedback signal F_SIG, and/or the second gain for determining the voltage level of the first compensation signal may change.

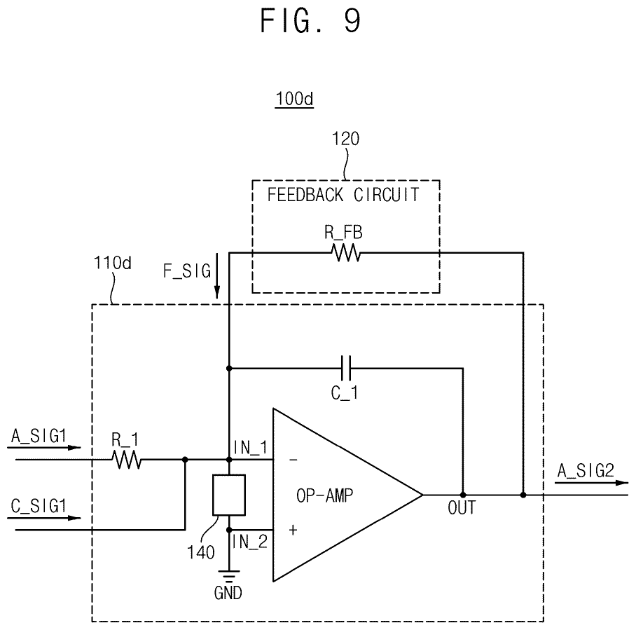

FIG. 9 is a circuit diagram illustrating an example of an input network included in a cyclic analog-to-digital converter according to some example embodiments.

Referring to FIG. 9, an input network 100d may include an integrator 110d and/or the feedback circuit 120. The integrator 110d may further include a negative impedance converter 140 compared to the integrator 110 in FIG. 2. Hereinafter, the descriptions repeated with or overlapping with descriptions of FIG. 2 will be omitted in the interest of brevity.

The negative impedance converter 140 may be connected between the first input terminal IN_1 and the second input terminal IN_2 of the operational amplifier OP-AMP.

In an ideal operational amplifier, a voltage gain is infinite, an input impedance is infinite, and a resistance of an output resistor is zero. However, in an actual operational amplifier, the voltage gain may not be infinite, the input impedance may not be infinite, and/or the resistance of the output resistor may not be zero. Therefore, the negative impedance converter 140 may perform an operation of controlling the operational amplifier to operate like the ideal operational amplifier.

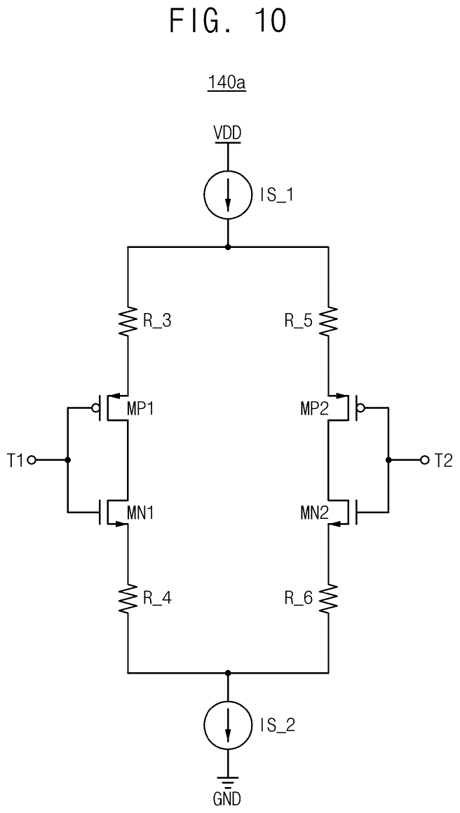

FIG. 10 is a circuit diagram illustrating an example of a negative impedance converter included in an integrator in FIG. 9.

Referring to FIG. 10, a negative impedance converter 140a may include a first current source IS_1, a second current source IS_2, a third resistor R_3, a fourth resistor R_4, a fifth resistor R_5, a sixth resistor R_6, a first p-channel metal-oxide semiconductor (PMOS) transistor MP1, a second PMOS transistor MP2, a first n-channel metal-oxide semiconductor (NMOS) transistor MN1, a second NMOS transistor MN2, a first terminal T1, and/or a second terminal T2.

The first current source IS_1 may be connected to a power supply voltage VDD, and the second current source IS_2 may be connected to a ground voltage GND. The third resistor R_3, the first PMOS transistor MP1, the first NMOS transistor MN1, and/or the fourth resistor R_4 may be connected in series, and/or the fifth resistor R_5, the second PMOS transistor MP2, the second NMOS transistor MN2, and/or the sixth resistor R_6 may be connected in series.

The third resistor R_3, the first PMOS transistor MP1, the first NMOS transistor MN1, and/or the fourth resistor R_4 connected in series, and/or the fifth resistor R_5, the second PMOS transistor MP2, the second NMOS transistor MN2, and/or the sixth resistor R_6 connected in series may be connected in parallel between the first current source IS_1 and the second current source IS_2.

A gate terminal of the first PMOS transistor MP1 and a gate terminal of the first NMOS transistor MN1 may be connected, and the first terminal T1 may be connected to the gate terminal of the first PMOS transistor MP1 and the gate terminal of the first NMOS transistor MN1. A gate terminal of the second PMOS transistor MP2 and a gate terminal of the second NMOS transistor MN2 may be connected, and the second terminal T2 may be connected to the gate terminal of the second PMOS transistor MP2 and the gate terminal of the second NMOS transistor MN2.

For example, the first terminal T1 may be connected to the first input terminal (e.g., IN_1 in FIG. 9) of the operational amplifier (e.g., OP-AMP of FIG. 9), and the second terminal T2 may be connected to the second input terminal (e.g., IN_2 in FIG. 9) of the operational amplifier OP-AMP. For example, the first terminal T1 may be connected to the second input terminal IN_2 of the operational amplifier OP-AMP, and the second terminal T2 may be connected to the first input terminal IN_1 of the operational amplifier OP-AMP.

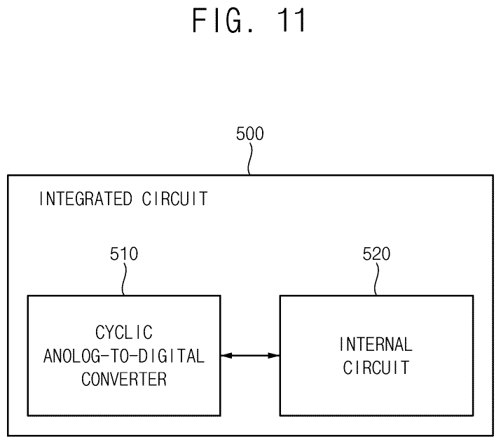

FIG. 11 is a block diagram illustrating an integrated circuit according to example embodiments.

Referring to FIG. 11, an integrated circuit 500 includes a cyclic analog-to-digital converter 510 and/or an internal circuit 520.

The cyclic analog-to-digital converter 510 may be the cyclic analog-to-digital converter according to some example embodiments. The cyclic analog-to-digital converter 510 may operate in continuous time, the input network including resistors and RC integrators may be designed without the sample-and-hold circuit, and/or the cyclic analog-to-digital converter 510 including the input network may operate in continuous time. Therefore, not only the power used in the cyclic analog-to-digital converter 510 may be reduced, but the power used in the input driver in front of the cyclic analog-to-digital converter 510 also may be reduced, such that the power efficiency of the entire system may be increased. A hardware area also may be reduced by omitting the sample-and-hold circuit.

The internal circuit 520 may transmit an analog signal, which is a continuous signal, to the cyclic analog-to-digital converter 510, operate based on the digital signal output from the cyclic analog-to-digital converter 510, and/or perform other specific operations.

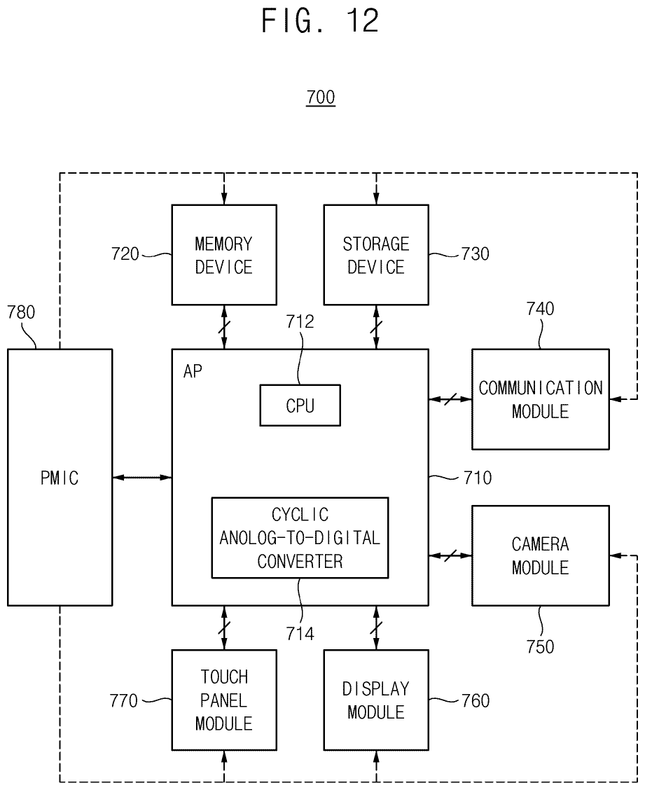

FIG. 12 is a block diagram illustrating an electronic system according to some example embodiments.

Referring to FIG. 12, an electronic system 700 includes a system on chip 710 and/or a plurality of functional modules 740, 750, 760, and/or 770. The electronic system 700 may further include a memory device 720, a storage device 730, and/or a power management integrated circuit (PMIC) 780.

In some example embodiments, the electronic system 700 may be any mobile system, such as a mobile phone, a smart phone, a tablet personal computer (PC), a personal digital assistant (PDA), a portable multimedia player (PMP), a digital camera, a music player, a portable game console, a navigation system, etc. The mobile system 740 may further include a wearable device, an Internet of Things (IoT) device, an Internet of Everything (IoE) device, an e-book, a virtual reality (VR) device, an augmented reality (AR) device, a drone, an automotive, etc.

The system on chip 710 may control the overall operation of the electronic system 700. In other words, the system on chip 710 may control the memory device 720, the storage device 730, and/or the plurality of functional modules 740, 750, 760, 770. For example, the system on chip 710 may be an application processor provided in the electronic system 700.

The system on chip 710 may include a central processing unit 712 and/or a cyclic analog-to-digital converter 714.

The central processing unit 712 may control the overall operation of the system on chip 710. For example, the central processing unit 712 may execute an operating system (OS) for operating the electronic system 700 and/or execute various applications that provide an internet browser, a game, a video, a camera, etc.

The cyclic analog-to-digital converter 714 may be the cyclic analog-to-digital converter according to example embodiments. The cyclic analog-to-digital converter 714 may operate in continuous time by designing the input network with resistors and RC integrators without the sample-and-hold circuit, the cyclic analog-to-digital converter 714 may operate in continuous time. Therefore, not only the power used in the cyclic analog-to-digital converter 714 may be reduced, but the power used in the input driver in front of the cyclic analog-to-digital converter 714 also may be reduced, such that the power efficiency of the entire system may be increased. A hardware area also may be reduced by eliminating the sample-and-hold circuit.

The memory device 720 and/or the storage device 730 may store data required for the operation of the electronic system 700. For example, the memory device 720 and/or the storage device 730 may store a boot image for booting the electronic system 700, a file system related to an operating system for driving the electronic system 700, a device driver related to an external device connected to the electronic system 700, an application running on the electronic system 700, etc.

Each, or one or more, of the plurality of function modules 740, 750, 760, and/or 770 may perform various functions of the electronic system 700. For example, the electronic system 700 may include a communication module 740 for performing a communication function (for example, a code division multiple access (CDMA) module, an long term evolution (LTE) module, an radio frequency (RF) module, an ultra wideband (UWB) module, a wireless local area network (WLAN) module, a worldwide interoperability for microwave access (WIMAX) module, etc.), a camera module 750 for performing a camera function, a display module 760 for performing a display function, a touch panel module 770 for performing a touch input function, etc. According to example embodiments, the electronic system 700 may further include a global positioning system (GPS) module, a microphone module, a speaker module, a gyroscope module, etc. However, it is obvious that the types of the multiple function modules 740, 750, 760, and/or 770 provided in the electronic system 700 are not limited thereto.

The power management device 780 may provide driving voltage to each, or one or more, of the system on chip 710, the memory device 720, the storage device 730, and/or the plurality of functional modules 740, 750, 760, and/or 770.

Some example embodiments may be applied to various electronic devices and systems that include the cyclic analog-to-digital converter. For example, some example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of some example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A cyclic analog-to-digital converter comprising:
an input network configured to receive a first analog signal and a first compensation signal, and to output a second analog signal based on the first analog signal and the first compensation signal, the input network including at least one resistor in a path for transmitting the first analog signal, the first and second analog signals being continuous signals;
a quantizer configured to output a digital signal based on the second analog signal and a second compensation signal;
a first compensation circuit configured to output the first compensation signal based on the digital signal; and
a second compensation circuit configured to output the second compensation signal based on the digital signal.

2. The cyclic analog-to-digital converter of claim 1, wherein the input network includes:
a feedback circuit configured to output a feedback signal based on the second analog signal; and
an integrator configured to output the second analog signal based on the first analog signal, the feedback signal, and the first compensation signal.

3. The cyclic analog-to-digital converter of claim 2, wherein the integrator includes:
an operational amplifier including a first input terminal configured to receive the first analog signal and the first compensation signal, a second input terminal connected to a ground voltage, and an output terminal configured to output the second analog signal;
a first resistor connected to the first input terminal of the operational amplifier; and
a first capacitor connected between the first input terminal and the output terminal of the operational amplifier.

4. The cyclic analog-to-digital converter of claim 3, wherein the feedback circuit includes a feedback resistor connected between the first input terminal and the output terminal of the operational amplifier, and
wherein the feedback circuit includes a feedback gain for determining a voltage level of the feedback signal, the feedback gain being based on a resistance of the feedback resistor and a capacitance of the first capacitor.

5. The cyclic analog-to-digital converter of claim 3, wherein the integrator includes a first gain for determining a voltage level of a difference signal, the first gain being based on a resistance of the first resistor and a capacitance of the first capacitor, and the difference signal corresponding to a difference between the first analog signal and the first compensation signal.

6. The cyclic analog-to-digital converter of claim 5, wherein the first compensation circuit includes:
a first digital-to-analog converter configured to convert the digital signal into the first compensation signal.

7. The cyclic analog-to-digital converter of claim 6, wherein the first compensation circuit includes a second gain for determining a voltage level of the first compensation signal, the second gain being based on a resistance of an internal resistor of the first digital-to-analog converter and a capacitance of the first capacitor.

8. The cyclic analog-to-digital converter of claim 6, wherein the quantizer is configured to operate based on a first clock signal, and
wherein the first digital-to-analog converter is configured to operate based on a second clock signal which is delayed from the first clock signal.

9. The cyclic analog-to-digital converter of claim 3, wherein the second compensation circuit includes:
a second digital-to-analog converter configured to convert the digital signal into the second compensation signal.

10. The cyclic analog-to-digital converter of claim 9, further comprising:
a second resistor connected between the input network and the quantizer.

11. The cyclic analog-to-digital converter of claim 10, wherein a ratio of a third gain for determining a voltage level of the second analog signal and a fourth gain for determining a voltage level of the second compensation signal is set based on a ratio of a resistance of an internal resistor of the second digital-to-analog converter and a resistance of the second resistor.

12. The cyclic analog-to-digital converter of claim 9, wherein the quantizer is configured to operate based on a first clock signal, and
wherein the second digital-to-analog converter is configured to operate based on a third clock signal which is delayed from the first clock signal.

13. The cyclic analog-to-digital converter of claim 3, wherein the integrator further includes:
a reset circuit connected between the first input terminal and the output terminal of the operational amplifier, the reset circuit configured to initialize the second analog signal.

14. The cyclic analog-to-digital converter of claim 13, wherein the reset circuit includes:
a first switch connected between the first input terminal and the output terminal of the operational amplifier.

15. The cyclic analog-to-digital converter of claim 3, wherein the integrator further includes:
a second capacitor and a second switch connected in series between the first input terminal and the output terminal of the operational amplifier.

16. The cyclic analog-to-digital converter of claim 3, wherein the integrator further includes:
a negative impedance converter connected between the first input terminal and the second input terminal of the operational amplifier.

17. An integrated circuit comprising:
a cyclic analog-to-digital converter configured to perform an analog-to-digital conversion; and
an internal circuit configured to transmit a first analog signal to the cyclic analog-to-digital converter, or to operate based on a digital signal output from the cyclic analog-to-digital converter, the first analog signal being a continuous signal, and
wherein the cyclic analog-to-digital converter includes:
an input network configured to output a second analog signal based on the first analog signal and a first compensation signal, the input network including at least one resistor in a path for transmitting the first analog signal, the second analog signal being a continuous signal;
a quantizer configured to output the digital signal based on the second analog signal and a second compensation signal;
a first compensation circuit configured to output the first compensation signal based on the digital signal; and
a second compensation circuit configured to output the second compensation signal based on the digital signal.

18. The integrated circuit of claim 17, wherein the input network includes:
a feedback circuit configured to output a feedback signal based on the second analog signal; and
an integrator configured to output the second analog signal based on the first analog signal, the feedback signal, and the first compensation signal,
wherein the integrator includes:
an operational amplifier including a first input terminal configured to receive the first analog signal and the first compensation signal, a second input terminal connected to a ground voltage, and an output terminal configured to output the second analog signal;
a first resistor connected to the first input terminal of the operational amplifier; and
a first capacitor connected between the first input terminal and the output terminal of the operational amplifier.

19. The integrated circuit of claim 18, wherein the first compensation circuit includes a first digital-to-analog converter configured to convert the digital signal into the first compensation signal,
wherein the second compensation circuit includes a second digital-to-analog converter configured to convert the digital signal into the second compensation signal,
wherein the quantizer is configured to operate based on a first clock signal,
wherein the first digital-to-analog converter and the second digital-to-analog converter are configured to operate based on a second clock signal which is delayed from the first clock signal, and
wherein the integrator further includes:
a reset circuit connected between the first input terminal and the output terminal of the operational amplifier, and configured to initialize the second analog signal; and
a second capacitor and a second switch connected in series between the first input terminal and the output terminal of the operational amplifier.

20. A cyclic analog-to-digital converter comprising:
an operational amplifier including a first input terminal configured to receive a first analog signal and a first compensation signal, a second input terminal connected to a ground voltage, and an output terminal configured to output a second analog signal, the operational amplifier configured to output the second analog signal based on the first analog signal and the first compensation signal, the first and second analog signals being continuous signals;
a first resistor connected to the first input terminal of the operational amplifier;
a first capacitor connected between the first input terminal and the output terminal of the operational amplifier;
a first switch connected between the first input terminal and the output terminal of the operational amplifier, the first switch configured to initialize the second analog signal;
a second capacitor and a second switch connected in series between the first input terminal and the output terminal of the operational amplifier;
a feedback resistor connected between the first input terminal and the output terminal of the operational amplifier, the feedback resistor configured to output a feedback signal based on the second analog signal;
a quantizer configured to output a digital signal based on the second analog signal, a second compensation signal, and a first clock signal;
a first digital-to-analog converter configured to output the first compensation signal based on the digital signal and a second clock signal, the second clock signal being delayed from the first clock signal; and
a second digital-to-analog converter configured to output the second compensation signal based on the digital signal and the second clock signal.
